(19) United States
(12) Patent Application Publication
(10) Pub. No.: US 2026/0164881 A1
(43) Pub. Date: Jun. 11, 2026

(54) Display Device Including Light Emitting Diode

(71) Applicant: LG Display Co., Ltd., Seoul (KR)

(72) Inventors: Kyu-Oh KWON, Paju-si (KR); Ju-Sang RHIM, Paju-si (KR); Ki-Yong YANG, Paju-si (KR); Seung-Jun LEE, Paju-si (KR)

(21) Appl. No.: 19/310,134

(22) Filed: Aug. 26, 2025

(30) Foreign Application Priority Data
Dec. 9, 2024 (KR) 10-2024-0181841

(51) Int. Cl. H10H 29/34; H10H 29/855

(52) U.S. Cl. CPC H10H 29/34; H10H 29/855

(57) ABSTRACT

A display device includes: a substrate; a first subpixel, a second subpixel and a third subpixel on the substrate; and a first light emitting diode in the first subpixel and emitting a first colored light, a second light emitting diode in the second subpixel and emitting a second colored light, and a third light emitting diode in the third subpixel and emitting a third colored light, wherein the first light emitting diode has a first bottom pattern, the second light emitting diode has a second bottom pattern, and the third light emitting diode has a third bottom pattern, and wherein the first bottom pattern, the second bottom pattern and the third bottom pattern are formed to be different from each other to have an exclusivity.

### CROSS-REFERENCE TO RELATED APPLICATION

The present application claims the priority of Republic of Korea Patent Application No. 10-2024-0181841 filed on Dec. 9, 2024, which is hereby incorporated by reference in its entirety.

### BACKGROUND

### Field of the Disclosure

The present disclosure relates to a display device, and more particularly, to a display device including a light emitting diode having a bottom pattern.

### Description of the Background

Recently, various flat panel display devices such as a liquid crystal display device (LCD), an organic light emitting diode (OLED) display device, and a field emission display (FED) device having excellent properties of a thin profile, a light weight and a low power consumption have been developed and applied to various fields.

Although the OLED display device among the various flat panel display devices has an advantage such that an additional light source is not required, the OLED display device has a disadvantage such that deterioration may occur by an external circumstance due to a property of an organic material vulnerable to moisture and oxygen.

To overcome the disadvantage, a display device using a light emitting diode chip (or a light emitting diode) of an inorganic material has been suggested.

The light emitting diode chip is attached to a display panel after the light emitting diode chip is formed on a growth substrate. To distinguish red, green, and blue light emitting diode chips from each other, the red, green, and blue light emitting diode chips are formed to have elliptical shapes having different long axes and different short axes.

As a resolution increases, a size of the light emitting diode chip decreases. As a result, an exclusivity according to a long axis and a short axis of the light emitting diode chip may be reduced, and the light emitting diode may be broken.

### SUMMARY

Accordingly, the present disclosure is directed to a display device that substantially obviates one or more of the problems due to limitations and disadvantages of the related art.

More specifically, the present disclosure provides a display device including a light emitting diode where color mixture is prevented or at least reduced and a fabrication process is optimized by forming bottom patterns of different shapes on the light emitting diode.

Further, the present disclosure is to provide a display device including a light emitting diode applicable to a high resolution by forming bottom patterns of different shapes on red, green, and blue light emitting diodes.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a substrate; a first subpixel, a second subpixel and a third subpixel on the substrate; and a first light emitting diode in the first subpixel and emitting a first colored light, a second light emitting diode in the second subpixel and emitting a second colored light, and a third light emitting diode in the third subpixel and emitting a third colored light, wherein the first light emitting diode has a first bottom pattern, the second light emitting diode has a second bottom pattern, and the third light emitting diode has a third bottom pattern, and wherein the first bottom pattern, the second bottom pattern and the third bottom pattern are formed to be different from each other to have an exclusivity.

In another embodiment, a light emitting diode includes: a first semiconductor layer; an active layer on the first semiconductor layer; a second semiconductor layer on the active layer; a first electrode connected to the first semiconductor layer; and a second electrode connected to the second semiconductor layer, wherein the first semiconductor layer has a bottom pattern of one of an embossed shape and an engraved shape.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure.

In the drawings:

FIG. 1 is a view showing a display device according to a first embodiment of the present disclosure;

FIG. 2 is a circuit diagram showing a subpixel of a display device according to a first embodiment of the present disclosure;

FIG. 3 is a cross-sectional view showing a subpixel of a display panel of a display device according to a first embodiment of the present disclosure;

FIG. 4 is a view showing an assembly substrate of a light emitting diode of a display device according to a first embodiment of the present disclosure;

FIG. 5 is a magnified view of a portion A of FIG. 4 according to an embodiment of the present disclosure;

FIG. 6 is a cross-sectional view showing a plurality of light emitting diodes and an assembly substrate of a display device according to a first embodiment of the present disclosure;

FIGS. 7A to 7C are cross-sectional views showing second light emitting diodes and assembly substrates of display devices according to a second embodiment, a third embodiment, and a fourth embodiment, respectively, of the present disclosure;

FIGS. 8A to 8C are cross-sectional views showing third light emitting diodes and assembly substrates of display devices according to a fifth embodiment, a sixth embodiment, and a seventh embodiment, respectively, of the present disclosure;

FIGS. 9A to 9D are plan views showing third assembly patterns of third light emitting diodes of display devices according to an eighth embodiment, a ninth embodiment, a tenth embodiment, and an eleventh embodiment, respectively, of the present disclosure;

FIG. 10 is a cross-sectional view showing a plurality of light emitting diodes and an assembly substrate of a display device according to a twelfth embodiment of the present disclosure; and

FIGS. 11A and 11B are cross-sectional views showing third light emitting diodes of display devices according to thirteenth and fourteenth embodiments, respectively, of the present disclosure.

### DETAILED DESCRIPTION

Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure may be sufficiently thorough and complete to assist those skilled in the art to fully understand the scope of the present disclosure. Further, the present disclosure is only defined by scopes of claims.

The shapes, sizes, ratios, angles, numbers, and the like, which are illustrated in the drawings to describe various example aspects of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

The term “display device” may include a display device in a narrow sense such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit may be expressed as “a display device”, and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or oxygen into the emitting element layer. In addition, the emitting element layer on the array may include an inorganic light emitting layer, for example, a nano-sized material layer or a quantum dot.

The thin film transistor of the present disclosure may include one of an oxide thin film transistor, an amorphous silicon thin film transistor, and a low temperature polycrystalline silicon thin film transistor.

Features of various embodiments of the present disclosure may be partially or entirely coupled to or combined with each other. They may be linked and operated technically in various ways as those skilled in the art may sufficiently understand. The aspects may be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

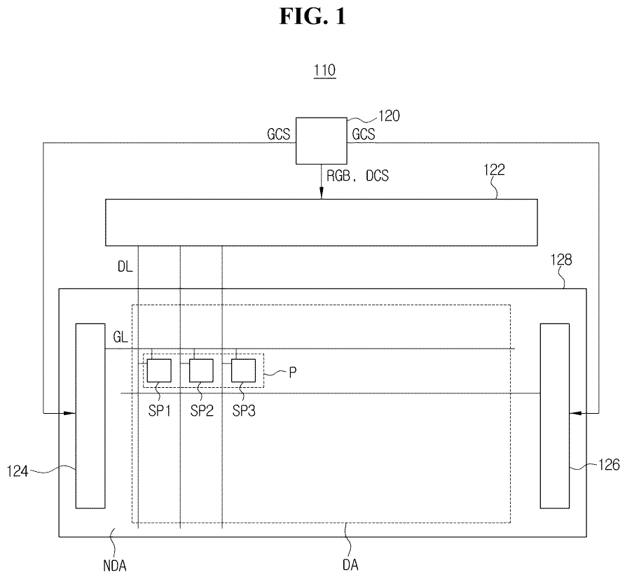

FIG. 1 is a view showing a display device according to a first embodiment of the present disclosure. Although the display device may be an organic light emitting diode (OLED) display device, it is not limited thereto. For example, the display device may be a micro light emitting diode (LED) display device or a mini light emitting diode (LED) display device.

In FIG. 1, a display device 110 according to a first embodiment of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB, a data control signal DCS, and a gate control signal GCS using an image signal and a plurality of timing signals including a data enable signal, a horizontal synchronization signal, a vertical synchronization signal and a clock signal transmitted from an external system such as a graphic card or a television system. The timing controlling unit 120 transmits the image data RGB and the data control signal DCS to the data driving unit 122 and transmits the gate control signal GCS to the first and second gate driving units 124 and 126.

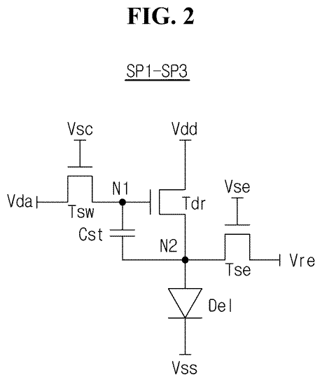

The data driving unit 122 generates a data signal (a data voltage) Vda (of FIG. 2) using the image data RGB and the data control signal DCS transmitted from the timing controlling unit 120 and transmits the data signal Vda to a data line DL of the display panel 128.

The first and second gate driving units 124 and 126 generate gate signals (a gate voltage) Vsc and Vse (of FIG. 2) using the gate control signal GCS transmitted from the timing controlling unit 120 and applies the gate signals Vsc and Vse to a gate line GL of the display panel 128.

The first and second gate driving units 124 and 126 may have a gate in panel (GIP) type to be formed in a non-display area NDA of a substrate of the display panel 128 having the gate line GL, the data line DL and a pixel P.

Although the first and second gate driving units 124 and 126 are disposed in both side portions of the display panel 128 in the first embodiment of FIG. 1, one gate driving unit may be disposed in one side portion of the display panel 128 in another embodiment.

The display panel 128 includes a display area DA at a central portion thereof and a non-display area NDA surrounding the display area DA. The display panel 128 displays an image using the gate signals Vsc and Vse and the data signal Vda. For displaying an image, the display panel 128 includes a plurality of pixels P, a plurality of gate lines GL and a plurality of data lines DL in the display area DA.

Each of the plurality of pixels P includes first, second, and third subpixels SP1, SP2 and SP3, and the gate line GL and the data line DL cross each other to define the first, second and third subpixels SP1, SP2 and SP3. Each of the first, second, and third subpixels SP1, SP2 and SP3 is connected to the gate line GL and the data line DL. For example, the first, second and third subpixels SP1, SP2 and SP3 may correspond to first, second and third colors, respectively, and the first, second and third colors may be red, green and blue colors, respectively.

Each of the first, second, and third subpixels SP1, SP2 and SP3 may include a plurality of transistors such as a switching transistor Tsw (of FIG. 2), a driving transistor Tdr (of FIG. 2) and a sensing transistor Tse (of FIG. 2), a storage capacitor Cst (of FIG. 2) and a light emitting diode Del (of FIG. 2).

FIG. 2 is a circuit diagram showing a subpixel of a display device according to a first embodiment of the present disclosure.

In FIG. 2, each of the first, second, and third subpixels SP1, SP2 and SP3 of the display panel 128 of the display device 110 according to a first embodiment of the present disclosure includes a switching transistor Tsw, a driving transistor Tdr, a sensing transistor Tse, a storage capacitor Cst, and a light emitting diode Del.

Although each of the first, second, and third subpixels SP1, SP2 and SP3 has a 3T1C structure having three transistors and one storage capacitor in the first embodiment of FIG. 2, each of the first, second, and third subpixels SP1, SP2 and SP3 may have one of a 6T1C structure having six transistors and one storage capacitor, a 7T1C structure having seven transistors and one storage capacitor and a 8T1C structure having eight transistors and one storage capacitor in another embodiment.

Although the switching transistor Tsw, the driving transistor Tdr, and the sensing transistor Tse may have a negative type in the first embodiment of FIG. 2, at least one of the switching transistor Tsw, the driving transistor Tdr and the sensing transistor Tse may have a positive type in another embodiment.

The switching transistor Tsw is switched according to a scan signal Vsc to transmit a data signal Vda to a first node N1.

A gate electrode of the switching transistor Tsw is connected to the gate line GL to receive the scan signal Vsc, a drain electrode of the switching transistor Tsw is connected to the data line DL to receive the data signal Vda, and a source electrode of the switching transistor Tsw is connected to the first node N1.

The driving transistor Tdr is switched according to a voltage of the first node N1 to transmit a high level signal (high level voltage) Vdd to a second node N2.

A gate electrode of the driving transistor Tdr is connected to the first node N1, a drain electrode of the driving transistor Tdr is connected to a high level power line to receive the high level signal Vdd, and a source electrode of the driving transistor Tdr is connected to the second node N2.

The sensing transistor Tse is switched according to a sensing signal (sensing voltage) Vse to transmit a reference signal (reference voltage) Vre to the second node N2 or transmit a voltage of the second node N3 to a reference line.

A gate electrode of the sensing transistor Tse is connected to the gate line GL to receive the sensing signal Vse, a drain electrode of the sensing transistor Tse is connected to the reference line to receive the reference signal Vre or transmit a voltage of the second node N2 to the reference line, and a source electrode of the sensing transistor Tse is connected to the second node N2.

The storage capacitor Cst keeps the data signal Vdata supplied to the first node N1 for one frame and stores a threshold voltage Vth of the driving transistor Tdr.

A first capacitor electrode of the storage capacitor Cst is connected to the first node N1, and a second capacitor electrode of the storage capacitor Cst is connected to the second node N2.

The light emitting diode Del emits a light of a luminance proportional to a current of the driving transistor Tdr.

An anode of the light emitting diode Del is connected to the second node N2, and a cathode of the light emitting diode Del is connected to a low level power line to receive a low level signal (low level voltage) Vss.

The source electrode of the switching transistor Tsw, the gate electrode of the driving transistor Tdr and the first capacitor electrode of the storage capacitor Cst constitute the first node N1, and the source electrode of the driving transistor Tdr, the source electrode of the sensing transistor Tse, the second capacitor electrode of the storage capacitor Cst and anode of the light emitting diode Del constitute the second node N2.

The light emitting diode Del may display an image having a luminance corresponding to the image data RGB according to a driving of subpixel circuits of the first, second and third subpixels SP1, SP2 and SP3.

A cross-sectional structure of each subpixel SP1, SP2 and SP3 of the display panel 128 of the display device 110 will be illustrated with reference to a drawing.

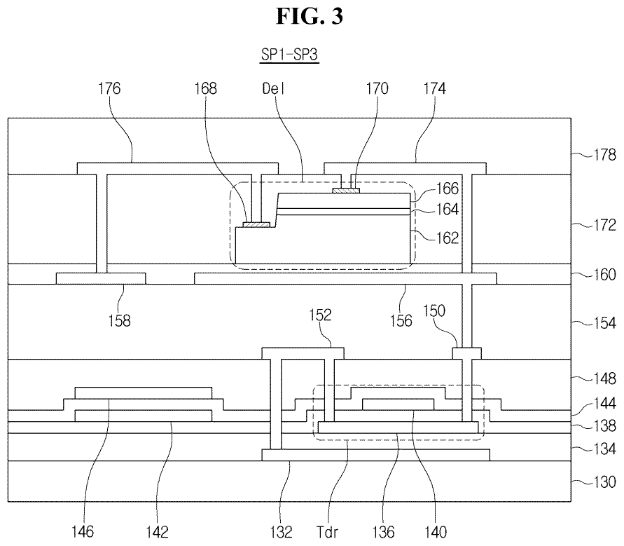

FIG. 3 is a cross-sectional view showing a subpixel of a display panel of a display device according to a first embodiment of the present disclosure.

In FIG. 3, a light shielding pattern 132 is disposed in each of the first, second, and third subpixels SP1, SP2, and SP3 on a substrate 130, and a first buffer layer 134 is disposed on the light shielding pattern 132 over the entire substrate 130.

The light shielding pattern 132 may block a light incident from a lower portion of the substrate 130. For example, the light shielding pattern 132 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

The first buffer layer 134 may block a moisture or an oxygen permeating from an exterior. For example, the first buffer layer 134 may have a single layer or a multiple layer of an inorganic insulating material such as silicon oxide (SiO₂) and silicon nitride (SiNx).

A semiconductor layer 136 is disposed on the first buffer layer 134 corresponding to the light shielding pattern 132 and a gate insulating layer 138 is disposed on the semiconductor layer 136 over the entire substrate 130.

The semiconductor layer 136 includes a channel region not doped with an impurity at a central portion thereof and source and drain regions doped with an impurity at both side portions of the channel region. For example, the semiconductor layer 136 may include a polycrystalline semiconductor material such as polycrystalline silicon or an oxide semiconductor material such as indium gallium zinc oxide (IGZO), zinc oxide (ZnO), tin oxide (SnO₂), copper oxide (Cu₂O), nickel oxide (NiO), indium tin zinc oxide (ITZO) and indium aluminum zinc oxide (IAZO).

For example, the gate insulating layer 138 may have a single layer or a multiple layer of an inorganic insulating material such as silicon oxide (SiO₂) and silicon nitride (SiNx).

A gate electrode 140 is disposed on the gate insulating layer 138 corresponding to the channel region of the semiconductor layer 136, a first capacitor electrode 142 separated from the gate electrode 140 is disposed on the gate insulating layer 138, and a first interlayer insulating layer 144 is disposed on the gate electrode 140 and the first capacitor electrode 142.

The gate electrode 140 and the first capacitor electrode 142 may have the same layer and the same material as each other. For example, the gate electrode 140 and the first capacitor electrode 142 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the first interlayer insulating layer 144 may have a single layer or a multiple layer of an inorganic insulating material such as silicon oxide (SiO₂) and silicon nitride (SiNx).

A second capacitor electrode 146 is disposed on the first interlayer insulating layer 144 corresponding to the first capacitor electrode 142 and a second interlayer insulating layer 148 is disposed on the second capacitor electrode 146 over the entire substrate 130.

For example, the second capacitor electrode 146 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the second interlayer insulating layer 148 may have a single layer or a multiple layer of an inorganic insulating material such as silicon oxide (SiO₂) and silicon nitride (SiNx).

The first capacitor electrode 142, the first interlayer insulating layer 144, and the second capacitor electrode 146 may collectively constitute the storage capacitor Cst.

A source electrode 150 and a drain electrode 152 spaced apart from each other are disposed on the second interlayer insulating layer 148 and a first planarizing layer 154 is disposed on the source electrode 150 and the drain electrode 152 over the entire substrate 130.

The source electrode 150 and the drain electrode 152 are connected to the source region and the drain region, respectively, of the semiconductor layer 136 through contact holes in the second interlayer insulating layer 148, the first interlayer insulating layer 144 and the gate insulating layer 138, and the drain electrode 152 is connected to the light shielding pattern 132 through a contact hole in the second interlayer insulating layer 148, the first interlayer insulating layer 144, the gate insulating layer 138 and the first buffer layer 134.

The source electrode 150 and the drain electrode 152 may have the same layer and the same material as each other. For example, the source electrode 150 and the drain electrode 152 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the first planarizing layer 154 may have a single layer or a multiple layer of an organic insulating material such as photoacryl and benzocyclobutene (BCB).

The semiconductor layer 136, the gate electrode 140, the source electrode 150 and the drain electrode 152 may constitute the driving transistor Tdr.

A connecting electrode 156 is disposed on the first planarizing layer 154 corresponding to the source electrode 150, a power line 158 spaced apart from the connecting electrode 156 is disposed on the first planarizing layer 154, and an adhesive layer 160 is disposed on the connecting electrode 156 and the power line 158 over the entire substrate 130.

The connecting electrode 156 is connected to the source electrode 150 through a contact hole in the first planarizing layer 154, and the connecting electrode 156 and the power line 158 may have the same layer and the same material as each other.

For example, the connecting electrode 156 and the power line 158 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the power line 158 may supply the low level signal Vss.

A first semiconductor layer 162 is disposed on the adhesive layer 160 corresponding to the connecting electrode 156, an active layer 164, a second semiconductor layer 166 and a second electrode 170 are sequentially disposed on a first side portion of the first semiconductor layer 162, and a first electrode 168 is disposed on a second side portion of the first semiconductor layer 162.

The first semiconductor layer 162 supplies an electron to the active layer 164, the second semiconductor layer 166 supplies a hole to the active layer 164, and the active layer 164 generates a light using an electron and a hole.

For example, the first semiconductor layer 162 may include negative type gallium nitride (n-GaN), the second semiconductor layer 166 may include positive type gallium nitride (p-GaN), and the active layer 164 may include a multi quantum well (MQW).

For example, the first electrode 168 may be a cathode, and the second electrode 170 may be an anode.

The first semiconductor layer 162, the active layer 164, the second semiconductor layer 166, the first electrode 168 and the second electrode 170 may constitute the light emitting diode Del (or light emitting diode chip).

A second planarizing layer 172 is disposed on the first and second electrodes 168 and 170 over the entire substrate 130, and first and second connecting lines 174 and 176 spaced apart from each other are disposed on the second planarizing layer 172 corresponding to the light emitting diode Del.

For example, the second planarizing layer 172 may have a single layer or a multiple layer of an organic insulating material such as photoacryl and benzocyclobutene (BCB).

The first connecting line 174 is connected to the connecting electrode 156 through a contact hole in the adhesive layer 160 and the second planarizing layer 172 and is connected to the second electrode 170 through a contact hole in the second planarizing layer 172.

The second connecting line 176 is connected to the power line 158 through a contact hole in the adhesive layer 160 and the second planarizing layer 172 and is connected to the first electrode 168 through a contact hole in the second planarizing layer 172.

For example, the first and second connecting lines 174 and 176 may include a transparent conductive material such as indium tin oxide (ITO) and indium zinc oxide (IZO).

An encapsulating layer 178 is disposed on the first and second connecting lines 174 and 176 over the entire substrate 130.

The encapsulating layer 178 prevents a permeation of a particle such as an oxygen or a moisture.

For example, the encapsulating layer 178 may have a single layer or a multiple layer of an inorganic insulating material such as silicon oxide (SiO₂) and silicon nitride (SiNx).

Although the light emitting diode Del exemplarily has a horizontal type in the first embodiment, the light emitting diode Del may have a vertical type in another embodiment.

The light emitting diode Del of the display device 110 may be attached to the substrate 130 through a self-assembly technology.

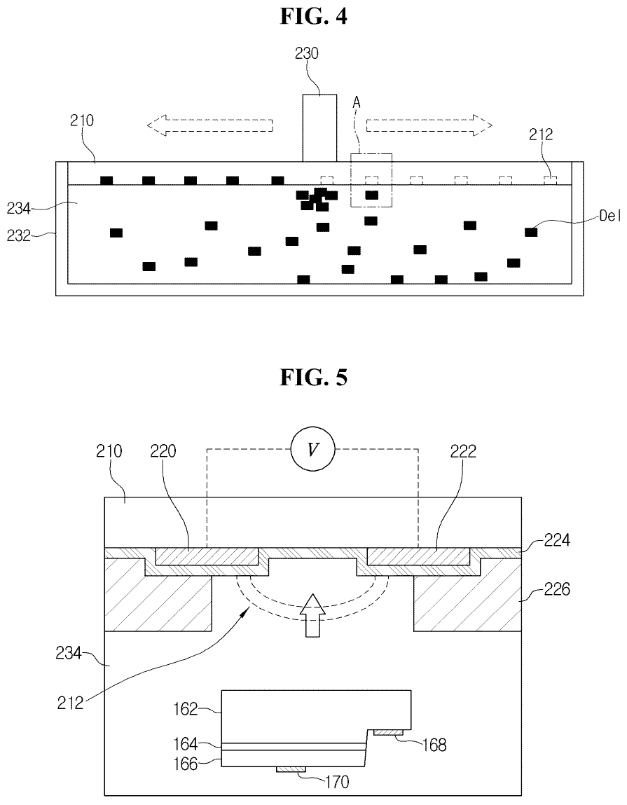

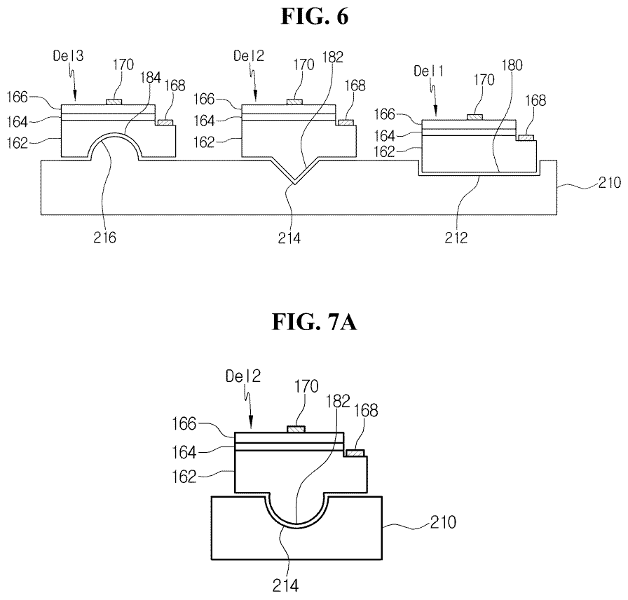

FIG. 4 is a view showing an assembly substrate of a light emitting diode of a display device according to a first embodiment of the present disclosure, and FIG. 5 is a magnified view of a portion A of FIG. 4 according to an embodiment of the disclosure.

In FIG. 4, an assembly substrate 210 having a plurality of assembly patterns 212 is disposed over a chamber 232, a magnetic rod 230 generating a magnetic field is disposed over the assembly substrate 210, and a fluid 234 including a plurality of light emitting diodes (LEDs) Del is disposed in the chamber 232.

The magnetic rod 230 may move along up, down, left and right directions and rotate, and the plurality of LEDs Del may be formed on a growth substrate and then be detached from the growth substrate.

For example, the fluid 234 may include a water such as a deionized water.

The plurality of LEDs Del move toward the assembly substrate 210 in the fluid 234 by the magnetic field of the magnetic rod 230, and the LED Del may have a magnetic layer.

For example, the magnetic layer may include a metal having a magnetic property such as nickel (Ni) and may be disposed in one of first and second electrodes 168 and 170 of the LED Del.

In FIG. 5, first and second assembly electrodes 220 and 222 spaced apart from each other are disposed on a bottom surface of the assembly substrate 210 and an insulating layer 224 is disposed on the first and second assembly electrodes 220 and 222 over the entire assembly substrate 210.

For example, the first and second assembly electrodes 220 and 222 may include a transparent conductive material or a metallic material, and the insulating layer 224 may have a single layer or a multiple layer of an inorganic insulating material or an organic insulating material.

A sidewall 226 is disposed on the insulating layer 224 corresponding to the first and second assembly electrodes 220 and 222. The sidewall 226 partially overlaps the first and second assembly electrodes 220 and 222, and a space surrounded by the sidewall 226 constitutes the assembly pattern 212.

When an alternating current (AC) voltage is applied to the first and second assembly electrodes 220 and 222, an electric field is generated between the first and second assembly electrodes 220 and 222 and the LED Del adjacent to the plurality of assembly patterns 212 among the plurality of LEDs Del in the fluid 234 may be assembled to the assembly pattern 212 by a dielectric phoretic force due to the electric field generated between the first and second assembly electrodes 220 and 222.

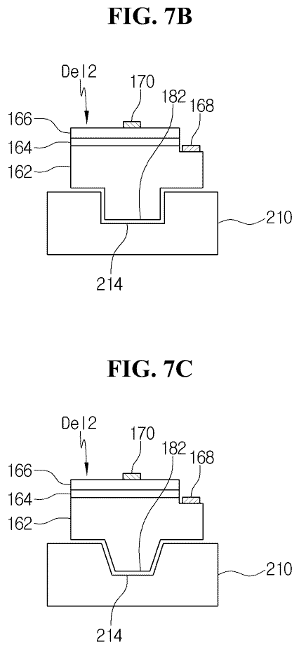

The plurality of LEDs Del include first, second, and third LEDs Del1, Del2 and Del3 (of FIG. 6) emitting first, second, and third colored lights, respectively, and having first, second and third bottom patterns, respectively. The plurality of assembly patterns 212 include first, second, and third assembly patterns 212, 214 and 216 (of FIG. 6) corresponding to the first, second and third bottom patterns 180, 182 and 184 of the first, second and third LEDs Del1, Del2 and Del3, respectively.

For example, the first, second and third colored lights may correspond to red, green and blue, respectively.

The first, second, and third bottom patterns 180, 182 and 184 of the first, second, and third LEDs Del1, Del2, and Del3 and the first, second, and third assembly patterns 212, 214 and 216 of the assembly substrate 210 have different embossed shapes, engraved shapes or flat shapes to have an exclusivity that a corresponding shape is selected.

When the first, second, and third LEDs Del1, Del2 and Del3 are properly assembled to the first, second, and third assembly patterns 212, 214 and 216, respectively, an electric force applied to the first, second and third LEDs Del1, Del2 and Del3 by the electric field of the first and second assembly electrodes 220 and 222 becomes greater than a magnetic force applied to the first, second, and third LEDs Del1, Del2, and Del3 by the magnetic field of the magnetic rod 230 so that the first, second, and third LEDs Del1, Del2 and Del3 cannot escape from and can be stably fixed to the first, second, and third assembly patterns 212, 214, and 216, respectively.

When the first, second, and third LEDs Del1, Del2, and Del3 are not properly assembled to the first, second, and third assembly patterns 212, 214, and 216, respectively, the magnetic force applied to the first, second, and third LEDs Del1, Del2, and Del3 by the magnetic field of the magnetic rod 230 becomes greater than the electric force applied to the first, second and third LEDs Del1, Del2 and Del3 by the electric field of the first and second assembly electrodes 220 and 222 so that the first, second and third LEDs Del1, Del2 and Del3 can escape from the first, second and third assembly patterns 212, 214 and 216, respectively. The first, second and third LEDs Del1, Del2 and Del3 having escaped from the first, second and third assembly patterns 212, 214 and 216 may float in the fluid 234 till the first, second and third LEDs Del1, Del2 and Del3 are properly assembled to the corresponding first, second and third assembly patterns 212, 214 and 216, respectively.

When the plurality of LEDs Del are properly assembled to the plurality of assembly patterns 212 of the assembly substrate 210, the assembly substrate 210 is disposed on the adhesive layer 160 of the substrate 130 of the display panel 128, and the plurality of LEDs Del of the plurality of assembly patterns 212 are transferred and attached to the adhesive layer 160 of each subpixel SP1, SP2 and SP3.

In another embodiment, a transfer step may be omitted using the substrate 130 having the driving transistor Tdr as the assembly substrate 210.

Disposition and shapes of the assembly substrate 210 and the plurality of LEDs Del will be illustrated with reference to drawings.

FIG. 6 is a cross-sectional view showing a plurality of light emitting diodes and an assembly substrate of a display device according to a first embodiment of the present disclosure.

In FIG. 6, before the first, second, and third LEDs Del1, Del2 and Del3 are disposed in the first, second, and third subpixels SP1, SP2, and SP3, respectively, of the display device 110 according to a first embodiment of the present disclosure, the first, second, and third LEDs Del1, Del2, and Del3 are assembled to the assembly substrate 210.

Each of the first, second, and third LEDs Del1, Del2 and Del3 of a lateral type includes the first semiconductor layer 162, the active layer 164, the second semiconductor layer 166, the first electrode 168 in a mesa region of the first semiconductor layer 162 and the second electrode 170 on a top surface of the second semiconductor layer 166. The first and second electrodes 168 and 170 are connected to the first and second semiconductor layers 162 and 166, respectively.

The first, second, and third LEDs Del1, Del2 and Del3 have first, second, and third bottom patterns 180, 182 and 184, respectively, having different shapes.

For example, the first bottom pattern 180 having the same area as a bottom surface of the first LED Del1 has a flat shape, the second bottom pattern 182 having an area smaller than an area of a bottom surface of the second LED Del2 has an embossed shape having a cross-section of a triangle shape, and the third bottom pattern 184 having an area smaller than an area of a bottom surface of the third LED Del3 has an engraved shape having a cross-section of a semicircle shape.

The second bottom pattern 182 may have one of a polygonal pyramid shape such as a triangular pyramid shape, a quadrangular pyramid shape, a pentagonal pyramid shape and a hexagonal pyramid shape, a cone shape and an elliptic cone shape in three dimensions, and the third bottom pattern 184 may have a hemisphere shape in three dimensions.

The assembly substrate 210 has first, second, and third assembly patterns 212, 214 and 216 corresponding to the first, second, and third bottom patterns 180, 182 and 184 of the first, second, and third LEDs Del1, Del2 and Del3, respectively.

For example, the first assembly pattern 212 having an area similar to or the same as an area of the bottom surface of the first LED Del1 may have an engraved shape having a cross-section of a rectangle shape, the second assembly pattern 214 having an area smaller than an area of the bottom surface of the second LED Del2 may have an engraved shape having a cross-section of a triangle shape, and the third assembly pattern 216 having an area smaller than an area of the bottom surface of the third LED Del3 may have an embossed shape of a cross-section of a semicircle shape.

The first assembly pattern 212 may have a rectangular prism (rectangular parallelepiped) shape or a cylinder shape in three dimensions, the second assembly pattern 214 may have one of a polygonal pyramid shape such as a triangular pyramid shape, a quadrangular pyramid shape, a pentagonal pyramid shape and a hexagonal pyramid shape, a cone shape and an elliptic cone shape in three dimensions, and the third assembly pattern 216 may have a hemisphere shape in three dimensions.

The second and third bottom patterns 182 and 184 of the second and third LEDs Del2 and Del3 do not correspond to the first assembly pattern 212 even when some of the second and third LEDs Del2 and Del3 is disposed to correspond to the first assembly pattern 212. As a result, the second and third LED Del2 and Del3 are not assembled to and easily escape from the first assembly pattern 212.

The third and first bottom patterns 184 and 180 of the third and first LEDs Del3 and Del1 do not correspond to the second assembly pattern 214 even when some of the third and first LEDs Del3 and Del1 is disposed to correspond to the second assembly pattern 214. As a result, the third and first LED Del3 and Del1 are not assembled to and easily escape from the second assembly pattern 214.

The first and second bottom patterns 180 and 182 of the first and second LEDs Del1 and Del2 do not correspond to the third assembly pattern 216 even when some of the first and second LEDs Del1 and Del2 is disposed to correspond to the third assembly pattern 216. As a result, the first and second LED Del1 and Del2 are not assembled to and easily escape from the third assembly pattern 216.

In the display device 110 according to a first embodiment of the present disclosure, the first, second and third bottom patterns 180, 182, and 184 of the first, second, and third LEDs Del1, Del2, and Del3 are formed to have a flat shape, an embossed shape and an engraved shape different from each other and having an exclusivity, and the first, second, and third assembly patterns 212, 214, and 216 of the assembly substrate 210 are formed to have shapes corresponding to the first, second, and third bottom patterns 180, 182, and 184 of the first, second and third LEDs Del1, Del2, and Del3. As a result, the exclusivity among the first, second and third LEDs Del1, Del2, and Del3 is improved, and a mixture of colors due to a mis-assembly of the first, second, and third LEDs Del1, Del2, and Del3 is prevented to obtain a relatively high resolution.

Although the first, second and third colors of the first, second and third LEDs Del1, Del2, and Del3 correspond to red, green, and blue, respectively, in the first embodiment, the first, second, and third colors may correspond to green, blue, and red, respectively, to blue, red, and green, respectively, or to colors different from each other in another embodiment.

The bottom patterns of the LEDs may have different shapes in another embodiment.

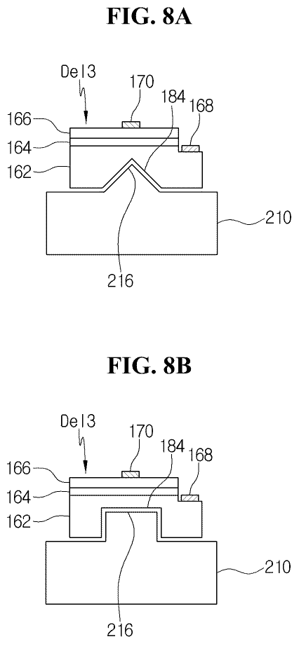

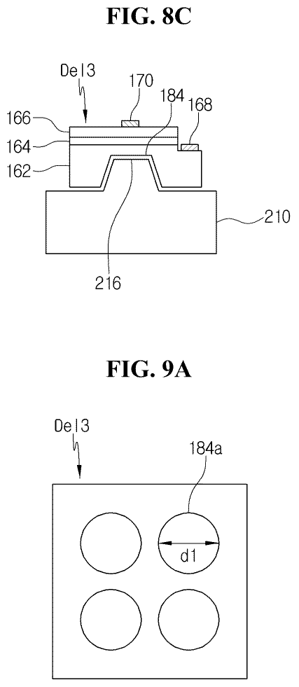

FIGS. 7A to 7C are cross-sectional views showing second light emitting diodes and assembly substrates of display devices according to the second embodiment, the third embodiment, and the fourth embodiment, respectively, of the present disclosure, and FIGS. 8A to 8C are cross-sectional views showing third light emitting diodes and assembly substrates of display devices according to the fifth embodiment, the sixth embodiment, and the seventh embodiment, respectively, of the present disclosure.

In FIG. 7A, a second LED Del2 of a lateral type of a display device according to a second embodiment of the present disclosure assembled to an assembly substrate 210 includes a first semiconductor layer 162, an active layer 164, a second semiconductor layer 166, a first electrode 168 in a mesa region of the first semiconductor layer 162 and a second electrode 170 on a top surface of the second semiconductor layer 166. The first and second electrodes 168 and 170 are connected to the first and second semiconductor layers 162 and 166, respectively.

The second LED Del2 has a second bottom pattern 182 having an area smaller than an area of a bottom surface of the second LED Del2. For example, the second bottom pattern 182 may have an embossed shape having a cross-section of a semicircle shape and may have a hemisphere shape in three dimensions.

The assembly substrate 210 has a second assembly pattern 214 corresponding to the second bottom pattern 182 and having an area smaller than an area of the bottom surface of the second LED Del2. For example, the second assembly pattern 214 may have an engraved shape having a cross-section of a semicircle shape and may have a hemisphere shape in three dimensions.

In FIG. 7B, a second LED Del2 of a lateral type of a display device according to a third embodiment of the present disclosure assembled to an assembly substrate 210 includes a first semiconductor layer 162, an active layer 164, a second semiconductor layer 166, a first electrode 168 in a mesa region of the first semiconductor layer 162 and a second electrode 170 on a top surface of the second semiconductor layer 166. The first and second electrodes 168 and 170 are connected to the first and second semiconductor layers 162 and 166, respectively.

The second LED Del2 has a second bottom pattern 182 having an area smaller than an area of a bottom surface of the second LED Del2. For example, the second bottom pattern 182 may have an embossed shape having a cross-section of a rectangle shape and may have one of a polygonal prism shape such as a triangular prism shape, a quadrangular prism shape, a pentagonal prism shape and a hexagonal prism shape, a cylinder shape and an elliptic cylinder shape in three dimensions.

The assembly substrate 210 has a second assembly pattern 214 corresponding to the second bottom pattern 182 and having an area smaller than an area of the bottom surface of the second LED Del2. For example, the second assembly pattern 214 may have an engraved shape having a cross-section of a rectangle shape and may have one of a polygonal prism shape such as a triangular prism shape, a quadrangular prism shape, a pentagonal prism shape and a hexagonal prism shape, a cylinder shape and an elliptic cylinder shape in three dimensions.

In FIG. 7C, a second LED Del2 of a lateral type of a display device according to a fourth embodiment of the present disclosure assembled to an assembly substrate 210 includes a first semiconductor layer 162, an active layer 164, a second semiconductor layer 166, a first electrode 168 in a mesa region of the first semiconductor layer 162, and a second electrode 170 on a top surface of the second semiconductor layer 166. The first and second electrodes 168 and 170 are connected to the first and second semiconductor layers 162 and 166, respectively.

The second LED Del2 has a second bottom pattern 182 having an area smaller than an area of a bottom surface of the second LED Del2. For example, the second bottom pattern 182 may have an embossed shape having a cross-section of a trapezoid shape and may have one of a truncated polygonal cone shape such as a truncated triangular cone shape, a truncated quadrangular cone shape, a truncated pentagonal cone shape, a truncated hexagonal cone shape and a truncated heptagonal cone shape, a truncated cone shape and a truncated elliptic cone shape in three dimensions.

The assembly substrate 210 has a second assembly pattern 214 corresponding to the second bottom pattern 182 and having an area smaller than an area of the bottom surface of the second LED Del2. For example, the second assembly pattern 214 may have an engraved shape having a cross-section of a trapezoid shape and may have one of a truncated polygonal cone shape such as a truncated triangular cone shape, a truncated quadrangular cone shape, a truncated pentagonal cone shape, a truncated hexagonal cone shape and a truncated heptagonal cone shape, a truncated cone shape and a truncated elliptic cone shape in three dimensions.

In FIG. 8A, a third LED Del3 of a lateral type of a display device according to a fifth embodiment of the present disclosure assembled to an assembly substrate 210 includes a first semiconductor layer 162, an active layer 164, a second semiconductor layer 166, a first electrode 168 in a mesa region of the first semiconductor layer 162 and a second electrode 170 on a top surface of the second semiconductor layer 166. The first and second electrodes 168 and 170 are connected to the first and second semiconductor layers 162 and 166, respectively.

The third LED Del3 has a third bottom pattern 184 having an area smaller than an area of a bottom surface of the third LED Del3. For example, the third bottom pattern 184 may have an engraved shape having a cross-section of a triangle shape and may have one of a polygonal cone shape such as a triangular cone shape, a quadrangular cone shape, a pentagonal cone shape and a hexagonal cone shape, a cone shape and an elliptic cone shape in three dimensions.

The assembly substrate 210 has a third assembly pattern 216 corresponding to the third bottom pattern 184 and having an area smaller than an area of the bottom surface of the third LED Del3. For example, the third assembly pattern 216 may have an embossed shape having a cross-section of a triangle shape and may have one of a polygonal cone shape such as a triangular cone shape, a quadrangular cone shape, a pentagonal cone shape and a hexagonal cone shape, a cone shape and an elliptic cone shape in three dimensions.

In FIG. 8B, a third LED Del3 of a lateral type of a display device according to a sixth embodiment of the present disclosure assembled to an assembly substrate 210 includes a first semiconductor layer 162, an active layer 164, a second semiconductor layer 166, a first electrode 168 in a mesa region of the first semiconductor layer 162, and a second electrode 170 on a top surface of the second semiconductor layer 166. The first and second electrodes 168 and 170 are connected to the first and second semiconductor layers 162 and 166, respectively.

The third LED Del3 has a third bottom pattern 184 having an area smaller than an area of a bottom surface of the third LED Del3. For example, the third bottom pattern 184 may have an engraved shape having a cross-section of a rectangle shape and may have one of a polygonal prism shape such as a triangular prism shape, a quadrangular prism shape, a pentagonal prism shape and a hexagonal prism shape, a cylinder shape and an elliptic cylinder shape in three dimensions.

The assembly substrate 210 has a third assembly pattern 216 corresponding to the third bottom pattern 184 and having an area smaller than an area of the bottom surface of the third LED Del3. For example, the third assembly pattern 216 may have an embossed shape having a cross-section of a rectangle shape and may have one of a polygonal prism shape such as a triangular prism shape, a quadrangular prism shape, a pentagonal prism shape and a hexagonal prism shape, a cylinder shape and an elliptic cylinder shape in three dimensions.

In FIG. 8C, a third LED Del3 of a lateral type of a display device according to a seventh embodiment of the present disclosure assembled to an assembly substrate 210 includes a first semiconductor layer 162, an active layer 164, a second semiconductor layer 166, a first electrode 168 in a mesa region of the first semiconductor layer 162, and a second electrode 170 on a top surface of the second semiconductor layer 166. The first and second electrodes 168 and 170 are connected to the first and second semiconductor layers 162 and 166, respectively.

The third LED Del3 has a third bottom pattern 184 having an area smaller than an area of a bottom surface of the third LED Del3. For example, the third bottom pattern 184 may have an engraved shape having a cross-section of a trapezoid shape and may have one of a truncated polygonal cone shape such as a truncated triangular cone shape, a truncated quadrangular cone shape, a truncated pentagonal cone shape, a truncated hexagonal cone shape and a truncated heptagonal cone shape, a truncated cone shape and a truncated elliptic cone shape in three dimensions.

The assembly substrate 210 has a third assembly pattern 216 corresponding to the third bottom pattern 184 and having an area smaller than an area of the bottom surface of the third LED Del3. For example, the third assembly pattern 216 may have an embossed shape having a cross-section of a trapezoid shape and may have one of a truncated polygonal cone shape such as a truncated triangular cone shape, a truncated quadrangular cone shape, a truncated pentagonal cone shape, a truncated hexagonal cone shape and a truncated heptagonal cone shape, a truncated cone shape and a truncated elliptic cone shape in three dimensions.

While one LED has one bottom pattern in the first embodiment, one LED may have at least two bottom patterns in another embodiment.

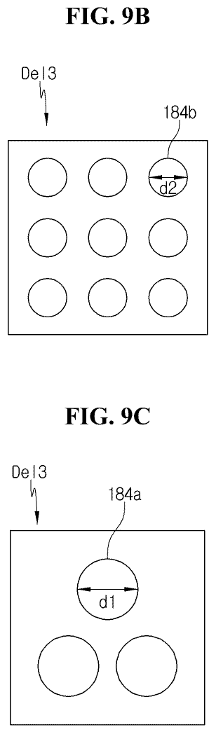

FIGS. 9A to 9D are plan views showing third assembly patterns of third light emitting diodes of display devices according to the eighth embodiment, the ninth embodiment, the tenth embodiment, and the eleventh embodiment, respectively, of the present disclosure.

In FIG. 9A, a third LED Del3 of a display device according to an eighth embodiment of the present disclosure includes a plurality of third-first bottom patterns 184a having an area smaller than an area of a bottom surface of the third LED Del3. For example, each of four third-first bottom patterns 184a has a circle shape of a first diameter d1 in a plan view.

In FIG. 9B, a third LED Del3 of a display device according to a ninth embodiment of the present disclosure includes a plurality of third-second bottom patterns 184b having an area smaller than an area of a bottom surface of the third LED Del3. For example, each of nine third-second bottom patterns 184b has a circle shape of a second diameter d2 smaller than the first diameter d1 in a plan view.

In FIG. 9C, a third LED Del3 of a display device according to a tenth embodiment of the present disclosure includes a plurality of third-first bottom patterns 184a having an area smaller than an area of a bottom surface of the third LED Del3. For example, each of three third-first bottom patterns 184a has a circle shape of a first diameter d1 in a plan view.

In FIG. 9D, a third LED Del3 of a display device according to an eleventh embodiment of the present disclosure includes a plurality of third-first bottom patterns 184a and a plurality of third-second bottom patterns 184b having an area smaller than an area of a bottom surface of the third LED Del3. For example, each of two third-first bottom patterns 184a has a circle shape of a first diameter d1 and each of three third-second bottom patterns 184b has a circle shape of a second diameter d2 smaller than the first diameter d1 in a plan view.

Although the third LED Del3 exemplarily has a plurality of third bottom patterns 184 in the eighth to eleventh embodiments of FIGS. 9A to 9D, the second LED Del2 may have a plurality of second bottom patterns 182 in another embodiment.

In another embodiment, the LED may have a vertical type.

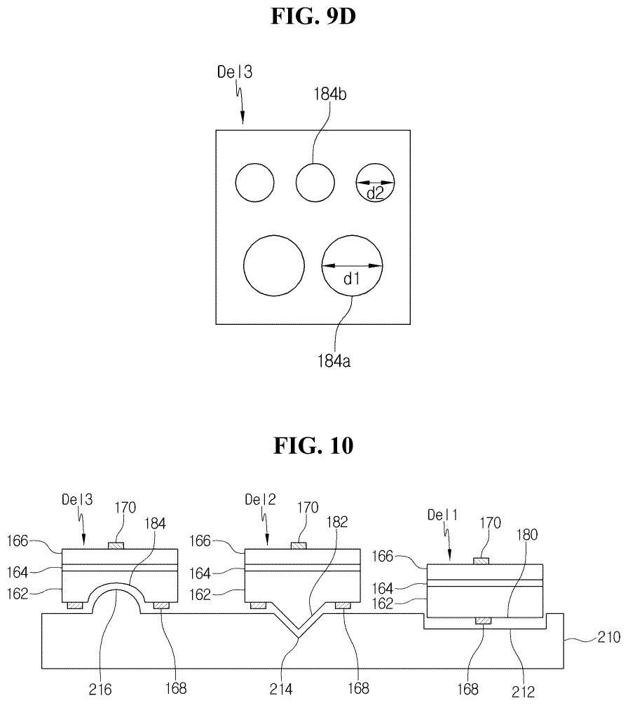

FIG. 10 is a cross-sectional view showing a plurality of light emitting diodes and an assembly substrate of a display device according to a twelfth embodiment of the present disclosure.

In FIG. 10, before first, second and third LEDs Del1, Del2 and Del3 are disposed in first, second, and third subpixels SP1, SP2 and SP3, respectively, of the display device according to a twelfth embodiment of the present disclosure, the first, second and third LEDs Del1, Del2 and Del3 are assembled to an assembly substrate 210.

Each of the first, second and third LEDs Del1, Del2 and Del3 of a vertical type includes a first semiconductor layer 162, an active layer 164, a second semiconductor layer 166, a first electrode 168 on a bottom surface of the first semiconductor layer 162 and a second electrode 170 on a top surface of the second semiconductor layer 166. The first and second electrodes 168 and 170 are connected to the first and second semiconductor layers 162 and 166, respectively.

The first, second and third LEDs Del1, Del2 and Del3 have first, second and third bottom patterns 180, 182 and 184, respectively, having different shapes.

For example, the first bottom pattern 180 having the same area as a bottom surface of the first LED Del1 has a flat shape, the second bottom pattern 182 having an area smaller than an area of a bottom surface of the second LED Del2 has an embossed shape having a cross-section of a triangle shape, and the third bottom pattern 184 having an area smaller than an area of a bottom surface of the third LED Del3 has an engraved shape having a cross-section of a semicircle shape.

In the second and third LEDs Del2 and Del3, the first electrode 168 may be disposed on the bottom surface of the first semiconductor layer 162 to have a ring shape having an open portion, and each of the second and third bottom patterns 182 and 184 may be disposed in the open portion of the first electrode 168.

The second bottom pattern 182 may have one of a polygonal pyramid shape such as a triangular pyramid shape, a quadrangular pyramid shape, a pentagonal pyramid shape and a hexagonal pyramid shape, a cone shape and an elliptic cone shape in three dimensions, and the third bottom pattern 184 may have a hemisphere shape in three dimensions.

The assembly substrate 210 has first, second and third assembly patterns 212, 214 and 216 corresponding to the first, second and third bottom patterns 180, 182 and 184 of the first, second and third LEDs Del1, Del2 and Del3, respectively.

For example, the first assembly pattern 212 having an area similar to or the same as an area of the bottom surface of the first LED Del1 may have an engraved shape having a cross-section of a rectangle shape, the second assembly pattern 214 having an area smaller than an area of the bottom surface of the second LED Del2 may have an engraved shape having a cross-section of a triangle shape, and the third assembly pattern 216 having an area smaller than an area of the bottom surface of the third LED Del3 may have an embossed shape of a cross-section of a semicircle shape.

The first assembly pattern 212 may have a rectangular prism (rectangular parallelepiped) shape or a cylinder shape in three dimensions, the second assembly pattern 214 may have one of a polygonal pyramid shape such as a triangular pyramid shape, a quadrangular pyramid shape, a pentagonal pyramid shape and a hexagonal pyramid shape, a cone shape and an elliptic cone shape in three dimensions, and the third assembly pattern 216 may have a hemisphere shape in three dimensions.

The second and third bottom patterns 182 and 184 of the second and third LEDs Del2 and Del3 do not correspond to the first assembly pattern 212 even when some of the second and third LEDs Del2 and Del3 is disposed to correspond to the first assembly pattern 212. As a result, the second and third LED Del2 and Del3 are not assembled to and easily escape from the first assembly pattern 212.

The third and first bottom patterns 184 and 180 of the third and first LEDs Del3 and Del1 do not correspond to the second assembly pattern 214 even when some of the third and first LEDs Del3 and Del1 is disposed to correspond to the second assembly pattern 214. As a result, the third and first LED Del3 and Del1 are not assembled to and easily escape from the second assembly pattern 214.

The first and second bottom patterns 180 and 182 of the first and second LEDs Del1 and Del2 do not correspond to the third assembly pattern 216 even when some of the first and second LEDs Del1 and Del2 is disposed to correspond to the third assembly pattern 216. As a result, the first and second LED Del1 and Del2 are not assembled to and easily escape from the third assembly pattern 216.

In the display device according to a twelfth embodiment of the present disclosure, the first, second and third bottom patterns 180, 182 and 184 of the first, second and third LEDs Del1, Del2 and Del3 are formed to have a flat shape, an embossed shape and an engraved shape different from each other and having an exclusivity, and the first, second and third assembly patterns 212, 214 and 216 of the assembly substrate 210 are formed to have shapes corresponding to the first, second and third bottom patterns 180, 182 and 184 of the first, second and third LEDs Del1, Del2 and Del3. As a result, the exclusivity among the first, second and third LEDs Del1, Del2 and Del3 is improved, and a mixture of colors due to a mis-assembly of the first, second and third LEDs Del1, Del2 and Del3 is prevented to obtain a relatively high resolution.

In another embodiment, a functional material layer may be disposed in the bottom pattern of the LED.

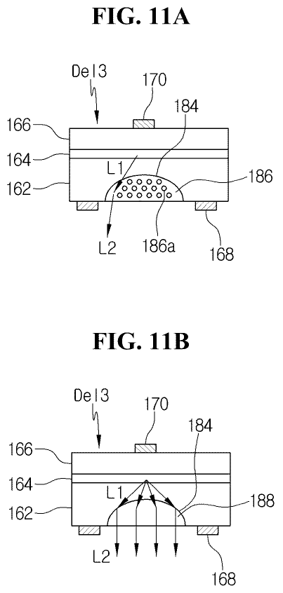

FIGS. 11A and 11B are cross-sectional views showing third light emitting diodes of display devices according to thirteenth and fourteenth embodiments, respectively, of the present disclosure.

In FIG. 11A, a third LED Del3 of a vertical type of a display device according to a thirteenth embodiment of the present disclosure includes a first semiconductor layer 162, an active layer 164, a second semiconductor layer 166, a first electrode 168 on a bottom surface of the first semiconductor layer 162 and a second electrode 170 on a top surface of the second semiconductor layer 166. The first and second electrodes 168 and 170 are connected to the first and second semiconductor layers 162 and 166, respectively.

The third LED Del2 has a third bottom pattern 184 having an area smaller than an area of a bottom surface of the third LED Del3. The third bottom pattern 184 may have an engraved shape having a cross-section of a semicircle shape and may have a hemisphere shape in three dimensions.

A wavelength converting layer 186 including a plurality of wavelength converting materials 186a is disposed in the third bottom pattern 184.

For example, the plurality of wavelength converting materials 186a may include a quantum dot or a nano optical material (NOM).

A first light L1 of a first wavelength is emitted from the active layer 164 of the third LED Del3, and a wavelength of the first light L1 is converted while the first light L1 passes through the wavelength converting layer 186. As a result, a second light L2 having a second wavelength different from the first wavelength is emitted from the third LED Del3.

In the display device according to a thirteenth embodiment of the present disclosure, since the wavelength converting layer 186 is disposed in the third bottom pattern 184 of an engraved shape of the third LED Del3, the wavelength of the light emitted from the third LED Del3 may be variously changed.

In FIG. 11B, a third LED Del3 of a vertical type of a display device according to a fourteenth embodiment of the present disclosure includes a first semiconductor layer 162, an active layer 164, a second semiconductor layer 166, a first electrode 168 on a bottom surface of the first semiconductor layer 162, and a second electrode 170 on a top surface of the second semiconductor layer 166. The first and second electrodes 168 and 170 are connected to the first and second semiconductor layers 162 and 166, respectively.

The third LED Del2 has a third bottom pattern 184 having an area smaller than an area of a bottom surface of the third LED Del3. The third bottom pattern 184 may have an engraved shape having a cross-section of a semicircle shape and may have a hemisphere shape in three dimensions.

A lens layer 188 is disposed in the third bottom pattern 184.

For example, the lens layer 188 may include a transparent insulating material having a refractive index greater than a refractive index of the first semiconductor layer 162.

A first light L1 of a first wavelength is emitted from the active layer 164 of the third LED Del3 and is refracted toward the bottom surface of the third LED Del3 at an interface between the first semiconductor layer 162 and the lens layer 188. As a result, a condensed second light L2 is emitted from the third LED Del3.

In the display device according to a fourteenth embodiment of the present disclosure, since the lens layer 188 is disposed in the third bottom pattern 184 of an engraved shape of the third LED Del3, the light emitted from the third LED Del3 may be condensed to improve a light extraction efficiency.

Consequently, in the display device according to the first to fourteenth embodiments of the present disclosure, the first, second, and third bottom patterns of the first, second, and third LEDs are formed to have a flat shape, an embossed shape and an engraved shape different from each other, and the first, second, and third assembly patterns of the assembly substrate are formed to correspond to the first, second and third bottom patterns, respectively. As a result, an exclusivity among the first, second and third LEDs is improved, and a mixture of colors due to a mis-assembly of the first, second and third LEDs is prevented to obtain a relatively high resolution.

It will be apparent to those skilled in the art that various modifications and variation may be made in the present disclosure without departing from the scope of the disclosure. Thus, it is intended that the present disclosure cover the modifications and variations of this disclosure provided they come within the scope of the appended claims and their equivalents.

What is claimed is:

1. A display device, comprising:
a substrate;
a first subpixel, a second subpixel and a third subpixel on the substrate; and
a first light emitting diode in the first subpixel and emitting a first colored light, a second light emitting diode in the second subpixel and emitting a second colored light, and a third light emitting diode in the third subpixel and emitting a third colored light,
wherein the first light emitting diode has a first bottom pattern, the second light emitting diode has a second bottom pattern, and the third light emitting diode has a third bottom pattern, and
wherein the first bottom pattern, the second bottom pattern and the third bottom pattern are formed to be different from each other to have an exclusivity.

2. The display device of claim 1, wherein the first bottom pattern, the second bottom pattern and the third bottom pattern have shapes different from each other to have an exclusivity.

3. The display device of claim 2, wherein the first bottom pattern has a flat shape, and the second bottom pattern and the third bottom pattern have three-dimensional shapes different from each other.

4. The display device of claim 3, wherein the second bottom pattern has an embossed shape, and the third bottom pattern has an engraved shape.

5. The display device of claim 3, wherein the second bottom pattern and the third bottom pattern have embossed shapes different from each other, or have engraved shapes different from each other.

6. The display device of claim 3, wherein an area of the first bottom pattern is same as an area of a bottom surface of the first light emitting diode.

7. The display device of claim 3, wherein:
an area of the second bottom pattern is smaller than an area of a bottom surface of the second light emitting diode,
an area of the third bottom pattern is smaller than an area of a bottom surface of the third light emitting diode, and
the second bottom pattern and the third bottom pattern each has a vertical cross-section of one of a semicircle shape, a triangle shape, a rectangle shape and a trapezoid shape.

8. The display device of claim 3, wherein the three-dimensional shapes of the second bottom pattern and the third bottom pattern each has one of a hemisphere shape, a polygonal pyramid shape, a cone shape, an elliptic cone shape, a polygonal prism shape, a cylinder shape, an elliptic cylinder shape, a truncated polygonal pyramid shape, a truncated cone shape and a truncated elliptic cone shape.

9. The display device of claim 1, wherein the second light emitting diode has a plurality of second bottom patterns sizes of which are same as or different from each other, and/or the third light emitting diode has a plurality of third bottom patterns sizes of which are same as or different from each other.

10. The display device of claim 2, wherein the third bottom pattern has an engraved shape,
wherein a wavelength converting layer including a wavelength converting material is disposed in the third bottom pattern, and
wherein the wavelength converting material includes at least one of a quantum dot and a nano optical material.

11. The display device of claim 2, wherein the third bottom pattern has an engraved shape,
wherein a lens layer is disposed in the third bottom pattern, and
wherein the lens layer includes a transparent insulating material having a refractive index greater than a refractive index of a first semiconductor layer of the third light emitting diode.

12. The display device of claim 1, wherein each of the first, second and third light emitting diodes comprises:
a first semiconductor layer;
an active layer on the first semiconductor layer;
a second semiconductor layer on the active layer;
a first electrode connected to the first semiconductor layer; and
a second electrode connected to the second semiconductor layer,
wherein the first bottom pattern, the second bottom pattern and the third bottom pattern are formed on a bottom surface of the first semiconductor layer of the first light emitting diode, a bottom surface of the first semiconductor layer of the second light emitting diode and a bottom surface of the first semiconductor layer of the third light emitting diode, respectively,
wherein the first electrode is disposed on a bottom surface of the first semiconductor layer, and the second electrode is disposed on a top surface of the second semiconductor layer, and
wherein each of the first electrode of the second light emitting diode and the first electrode of the third light emitting diode has a ring shape including an open portion, and the second bottom pattern and the third bottom pattern are disposed in the open portion, respectively.

13. The display device of claim 1, wherein sizes of the first bottom pattern, the second bottom pattern and the third bottom pattern are different from each other to have an exclusivity.

14. The display device of claim 13, wherein the first bottom pattern has a flat shape having the same area as an area of a bottom surface of the first light emitting diode, and the second bottom pattern and the third bottom pattern have three-dimensional shapes sizes of which are different from each other but shapes are same.

15. A light emitting diode, comprising:
a first semiconductor layer;
an active layer on the first semiconductor layer;
a second semiconductor layer on the active layer;
a first electrode connected to the first semiconductor layer; and
a second electrode connected to the second semiconductor layer,
wherein the first semiconductor layer has a bottom pattern of one of an embossed shape and an engraved shape.

16. The light emitting diode of claim 15, wherein an area of the bottom pattern is smaller than an area of a bottom surface of the first semiconductor layer, and the bottom pattern has a vertical cross-section of one of a semicircle shape, a triangle shape, a rectangle shape and a trapezoid shape.

17. The light emitting diode of claim 15, wherein the bottom pattern has one of a hemisphere shape, a polygonal pyramid shape, a cone shape, an elliptic cone shape, a polygonal prism shape, a cylinder shape, an elliptic cylinder shape, a truncated polygonal pyramid shape, a truncated cone shape and a truncated elliptic cone shape in three dimensions.

18. The light emitting diode of claim 15, wherein the first electrode is disposed on a bottom surface of the first semiconductor layer, and the second electrode is disposed on a top surface of the second semiconductor layer, and
wherein the first electrode has a ring shape including an open portion, and the bottom pattern is disposed in the open portion.

19. The light emitting diode of claim 15, wherein the bottom pattern has an engraved shape,
wherein a wavelength converting layer including a wavelength converting material is disposed in the bottom pattern, and
wherein the wavelength converting material includes at least one of a quantum dot and a nano optical material.

20. The light emitting diode of claim 15, wherein the bottom pattern has an engraved shape,
wherein a lens layer is disposed in the bottom pattern, and
wherein the lens layer includes a transparent insulating material having a refractive index greater than a refractive index of the first semiconductor layer.
